(19) United States
(12) Patent Application Publication
(10) Pub. No.: US 2018/0261412 A1
(43) Pub. Date: Sep. 13, 2018

(54) SWITCHING APPARATUS AND METHOD FOR ACTUATING A SWITCHING DEVICE

(71) Applicant: Phoenix Contact GmbH & Co. KG, Blomberg (DE)

(72) Inventors: Elmar SCHAPER, Lugde (DE); Bernd SCHULTZ, Hoxter (DE); Lutz HEUER, Blomberg (DE); Stephan HANSMEIER, Bad Salzuflen (DE); Dirk PLEWKA, Nieheim (DE); Alexander GUNTER, Barntrup (DE)

(73) Assignee: Phoenix Contact GmbH & Co. KG, Blomberg (DE)

(21) Appl. No.: 15/779,484

(22) PCT Filed: Nov. 25, 2016
(86) PCT No.: PCT/EP2016/078825

§ 371 Date: May 25, 2018

(30) Foreign Application Priority Data
Nov. 27, 2015 (DE) 10 2015 120 670.6

(51) Int. Cl. H01H 47/22; H01H 47/00; H01H 9/54; H02J 9/06; G01R 31/02

(52) U.S. Cl. CPC H01H 47/22; H01H 47/002; H01H 9/548; H02P 27/08; H02J 9/06; G01R 31/028; H01H 9/542

(57) ABSTRACT

A switching unit for controlling at least one switching element, includes a control unit adapted to control the at least one switching element; a connection for applying a supply voltage for power supply of the control unit; an energy storage connectable to the connection for applying a supply voltage and adapted, when the supply voltage drops or fails, to supply the control unit with power that is sufficient to control the at least one switching element such that the switching element executes a predetermined switching operation; wherein the switching unit includes means for monitoring the operability of the energy storage. Furthermore, a method for controlling at least one switching element using the switching unit.

### FIELD

The invention relates to a switching unit for controlling a switching element, in particular for switching on and off an electrical load such as an electric motor, and also relates to a corresponding method for controlling a switching element.

### BACKGROUND

Switching units for controlling switching elements are used in automation technology, for example, in particular for switching on and off electrical loads such as electric motors. In particular, electromechanical switches and/or semiconductor switches are used as switching elements.

Electromechanical switches such as for example relays have the advantage of exhibiting a low internal resistance and therefore low loss. However, arcing occurs upon switching, which damages the contacts over time. Semiconductor switches such as thyristors or TRIACs, by contrast, allow for switching substantially without wear, however, they have a higher internal resistance and thus generate heat loss requiring some efforts for dissipation of the heat. So-called hybrid switches comprise an electromechanical switch and a semiconductor switch connected in parallel, wherein the semiconductor switch takes over the current during the switching operation, so that the electromechanical switch can be switched in the zero-current state. Hybrid switches thus combine the low wear of semiconductor technology and the low loss of relay technology, and such switches are typically controlled using a switching unit which includes a microprocessor for control purposes.

However, even if hybrid switches are used, for example in motor switches, there is the problem that a failure of the supply voltage causes an uncontrolled shutdown of the output stage and therefore opening of the mechanical contacts, and due to the uncontrolled shutdown considerable wear is caused in particular in the mechanical contacts. Regardless of the dimensioning of the contacts, this leads to a limitation of service life.

The thyristors or TRIACs of a hybrid switch turn off the current in the current zero crossing and thus make it possible to interrupt current flow virtually without wear. However, for this purpose it is necessary, for example in a relay, to hold the mechanical contacts in their position until the switch-off process is completed. It has therefore been known to use an energy buffer in switching units, in order to be able to still power the relays for this time.

For example, WO 2014/032718 A1 describes a switchgear for controlling energy supply of a downstream electric motor. The switchgear has a supply connection to which a supply source can be connected via an emergency stop switch, which supply source provides a supply voltage of 24 volts, for example. Furthermore, the prior art switchgear has connections for being connected to a power grid. Further connections are provided for connecting an electric motor. A plurality of electromechanical switches and semiconductor switches are provided in order to be able to connect the electric motor to or disconnect it from the power grid. Furthermore, a control unit is implemented in the switchgear, which is able to provide the required switching signals, i.e. the required excitation energy for the respective switches using the electrical energy obtained via the supply connection. Furthermore, the switchgear includes an energy storage which is able to supply electrical energy to the control unit if the supply voltage at the supply connection drops into a critical range, so that the control unit can provide the required switching signals for the respective switches. In other words, via the supply connection or by the energy storage, the control unit is supplied with the amount of energy that it needs to close an electromechanical switch or to keep it closed and to be able to hold a semiconductor switch in the conductive state.

A similar switchgear is known from WO 2014/075742 A1, in which the electric motor is automatically switched off in controlled manner when a first voltage threshold value is undershot, wherein in the case of a switch-off, the time duration between the undershooting of the first voltage threshold value and the undershooting of a second voltage threshold value is measured and the control unit outputs a signal if this time duration is below a critical time value. In this way, it is possible to determine the wear of the energy storage when executing an automatic switch-off of the electric motor. The signal can be used to generate a device error, whereby reconnection of the switchgear can be prevented, so that wear on the switch contacts due to uncontrolled shutdown can be avoided once the wear of the energy storage has been detected. However, if no automatic switch-off is performed for a rather long time, an uncontrolled shutdown may still happen if in the meantime wear of the energy storage has occurred, so that the energy storage has no longer sufficient energy to perform a controlled switch-off.

### SUMMARY

The present invention is based on the object to show a way how to improve a switching unit for controlling a switching element and to provide a correspondingly improved method for controlling a switching element.

This object is achieved with the features of the independent claims. Advantageous embodiments are specified in the dependent claims.

Accordingly, a switching unit for controlling at least one switching element comprises a control unit which is adapted to control the at least one switching element, a connection for applying a supply voltage for power supply of the control unit, an energy storage connectable to the connection for applying a supply voltage, the energy storage being adapted, in the event of a drop in or failure of the supply voltage, to supply the control unit with power sufficient to control the at least one switching element such that the switching element executes a predetermined switching operation. Furthermore, the switching unit comprises means for monitoring the operability of the energy storage, and the monitoring is in particular performed continuously, i.e. the operability of the energy storage is checked at predetermined times, wherein these times are in particular chosen such that between two checking times it is typically impossible that wear of the energy storage occurs, which would prevent the control unit from controlling the at least one switching element to execute the predetermined switching operation.

A method for controlling at least one switching element using a switching unit, in particular a switching unit as described above, comprises applying a supply voltage to the switching unit for power supply of a control unit of the switching unit, wherein the at least one switching element is controlled by the control unit; and wherein when the supply voltage drops or fails, the control unit is supplied with power by an energy storage that is connectable to the supply voltage, the power being sufficient to control the at least one switching element such that the switching element executes a predetermined switching operation; and wherein the method comprises monitoring the operability of the energy storage, wherein the monitoring is in particular performed continuously.

What can be considered as a key idea of the invention, therefore, is to perform continuous monitoring of an energy storage of a switching unit used for storing electrical energy so as to reliably avoid an uncontrolled shutdown due to wear of the energy storage, in particular uncontrolled opening of an electromechanical switch.

As a further preferred measure for improving a switching unit, it may furthermore advantageously be provided for the switching unit to be decoupled from further units which are connected to the same supply voltage, so as to prevent energy of the energy storage from draining to these further units.

According to a further preferred measure for improving a switching unit, the switching unit may advantageously use a pulse-width modulated signal for controlling the switching element, wherein the duty cycle of the pulse-width modulated switching signal is controlled as a function of predetermined parameters so as to achieve an increase in efficiency and to allow for the smallest possible dimensioning of the energy storage.

The method advantageously comprises to disconnect, at predetermined times, in particular cyclically, the energy storage from the power supply device for a predetermined period of time, wherein the predetermined period of time is selected such that in the operational state of the energy storage the energy stored in the energy storage does not fall below the energy required to perform the predetermined switching operation during the predetermined period of time; wherein it is furthermore advantageously contemplated to measure a measurand associated with the energy storage, which is a measure of the energy stored in the energy storage, to compare the measured value with a predetermined threshold value, and to determine the operability of the energy storage on the basis of the comparison result.

Preferably, upon detection that the operability of the energy storage is reduced by a predetermined amount, the at least one switching element is controlled such that the switching element performs the predetermined switching operation, and alternatively or additionally an error message is generated.

The predetermined switching operation in particular comprises a switching sequence for safe switch-off of an electrical load that is switched on and off via the at least one switching element.

According to an advantageous embodiment of the method it is furthermore contemplated that the switching unit is decoupled from further units, in particular from further switching units connected to the same supply voltage, so as to prevent energy stored in the energy storage from draining to the further units.

Advantageously, the control unit controls the at least one switching element using a pulse-width modulated switching signal, wherein the duty cycle of the pulse-width modulated switching signal is controlled by the control unit as a function of the switching state of the switching element, and/or as a function of the supply voltage, and/or as a function of an ambient temperature of the switching element. Preferably, the supply voltage is monitored using a voltage measuring device connected to the control unit.

### BRIEF DESCRIPTION OF THE DRAWINGS

The invention will now be explained in more detail by way of some exemplary embodiments in conjunction with the drawings, wherein the same reference numerals designate the same or equivalent components, and wherein:

FIG. 1 schematically illustrates a preferred embodiment of a switching unit according to the invention;

FIG. 2 schematically illustrates a plurality of switching units connected to a shared emergency stop chain;

FIG. 3 schematically illustrates an exemplary profile of the voltage available for power supply of the control unit of the switching unit, with and without a diode used for decoupling, and the start of a switch-off sequence being dependent thereon;

FIG. 4 schematically illustrates an exemplary voltage profile at the energy storage of a switching unit during a regularly performed functional check of the energy storage for monitoring purposes, the corresponding switch position of the switch used to disconnect the energy storage from the supply voltage, and the motor operation, both in case of an operational and of a defective energy storage.

### DETAILED DESCRIPTION

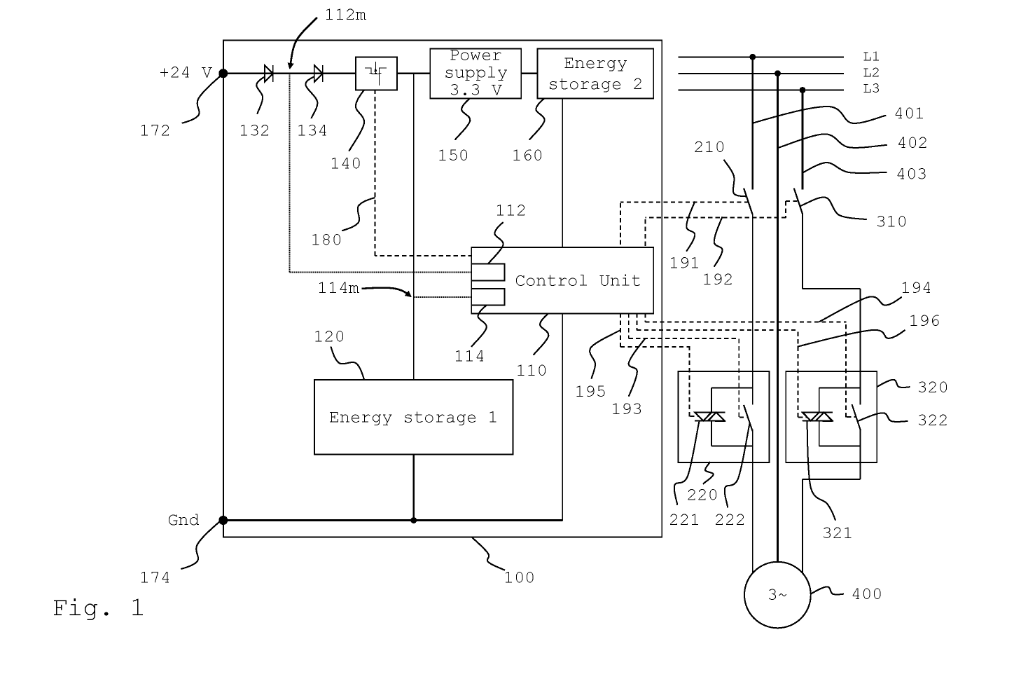

FIG. 1 shows an exemplary switching unit 100 for controlling at least one switching element, wherein the at least one switching element comprises switching elements 210, 221, 222, 310, 321, and 322 in the present example, which serve to switch on and off an electrical load 400, wherein in the illustrated example the load is provided in the form of a three-phase motor. It should be noted that the at least one switching element may advantageously be integrated in the switching unit 100 as well.

Three-phase motor 400 is connected to a power grid, which is a three-phase low-voltage power grid with the three conductors L1, L2, and L3 in the illustrated example. Three-phase motor 400 is connected to the conductors via respective current paths 401, 402, and 403.

For switching on and off the three-phase motor 400, a series connection of an electromechanical switch 210 and a hybrid switch 220 is connected into current path 401, hybrid switch 220 being composed of a semiconductor switch 221 and an electromechanical switch 222 connected in parallel, and similarly, a series connection of an electromechanical switch 310 and a hybrid switch 320 is connected into current path 403, hybrid switch 320 being composed of a semiconductor switch 321 and an electromechanical switch 322 connected in parallel. The electromechanical switches 210, 222, 310, and 321 are implemented as relays, for example, and semiconductor switches 221 and 322 are implemented as TRIACs, for example.

Switching elements 210, 221, 222, 310, 321, and 322 are controlled by control unit 110 of switching unit 100. In FIG. 1, the controlling is indicated by dashed lines 191 to 196. The controlling of switching elements 210, 221, 222, 310, 321, and 322 is typically effected using respective control circuits, not illustrated in FIG. 1. For performing the control functions, control unit 110 preferably includes a microprocessor. Furthermore, switching unit 100 may be connected to a higher-level switching device and may receive switching commands therefrom for switching on or off the three-phase motor 400.

Switching unit 100 is connected to a supply voltage, which in the illustrated example provides a DC voltage of 24 V, at a supply voltage connection of switching unit 100, consisting of connection terminals 172 and 174, terminal 174 being connected to ground. The supply voltage may for example be provided by an external power supply unit, not shown in FIG. 1.

The supply voltage is used to supply the control unit 110. In order to ensure controlling of the switching elements such that a predetermined switching operation is executed even in case the supply voltage drops or fails, a first energy storage 120 is provided, which is connectable to the supply voltage connection, and which will still supply power to the control unit 110 for a certain time, when the supply voltage drops or fails.

In order to continuously monitor the functioning of the energy storage, the switching unit 100 comprises means for monitoring the operability of the energy storage 120. In the illustrated example, these include a switch 140 that can be controlled by control unit 110. The controlling of switch 140 is indicated by dashed line 180.

At predetermined times, the energy storage 120 is disconnected from the power supply for a predetermined period of time by opening the switch 140 under control of control unit 110, and the voltage at energy storage 120 is measured. For this purpose, control unit 110 comprises a voltage measuring device 114 which measures the voltage at measuring point 114m during the predetermined period of time, wherein digital measured values which can be processed by the microprocessor of control unit 120 can be provided through A/D conversion. The voltage measured at energy storage 120 is compared with at least one predetermined reference or threshold value and is preferably stored in control unit 110.

The switch-off time, i.e. the predetermined period of time for which the energy storage 120 is disconnected from the power supply, can preferably be chosen to be very short, so that the disconnection of the energy storage 120 has no effect on the functioning of the control unit 110. The duration may, for example, be about 100 ms. However, it is also possible to choose any other suitable duration which is higher or lower at least or at most by a factor of 2, 5, 10, 20, or 100, for example. In the illustrated example, for this purpose it is provided for the control unit 120 to be powered by an own internal power supply 150 with an own, i.e. second energy storage 160, wherein in the illustrated example the power supply 150 provides a voltage of 3.3 V.

In the illustrated example, energy storages 120 and 160 are implemented as capacitors. When wear or aging of the capacitor 120 occurs, the capacitance of capacitor 120 decreases, and thus its ability to store electrical energy, or its operability. A reduction in the operability of energy storage 120 can be detected by measuring the voltage at energy storage 120, since in case of reduced operability the voltage will drop faster after disconnecting the energy storage 120 from the power supply than in the fully operational state.

It should be noted that the monitoring of the operability of the energy storage is preferably only performed when the three-phase motor 400 is in operation, i.e. when the control unit 110 consumes power for controlling switching elements 210, 221, 222, 310, 321, and 322.

If, after disconnecting the energy storage 120 from the power supply, a first predetermined threshold value or level is undershot, the three-phase motor 400 will initially remain in operation. The detection of an undershooting of the first predetermined threshold value advantageously serves to identify whether the functional check mechanism, i.e. the disconnecting of energy storage 120 from the power supply by triggering switch 140, works properly.

A reduction in the operability of energy storage 120 by a predetermined amount is detected by the fact that the voltage measured at energy storage 120 undershoots a second threshold value or level. As soon as the undershooting of this second threshold value is detected, the three-phase motor is switched off.

The predetermined amount of decrease in operability of the energy storage 120 and thus the second threshold value are preferably selected such that when the second energy threshold is undershot, the energy storage 120 is still capable of providing sufficient energy to the control unit to control the switching elements 210, 221, 222, 310, 321, and 322 so that a predetermined switching operation is executed. The predetermined switching operation in particular comprises a proper sequential switch-off of the three-phase motor 400, whereby in particular wear of the electromechanical switches 210, 222, 310, and 322 is prevented.

The voltage measurement at energy storage 120 provides a value representing the energy still available in energy storage 120. The energy still available upon initiation of the switch-off sequence can advantageously also be used to store, in a device memory of the switching unit 100, the device status of switching unit 100, for example comprising diagnostic data relating to the switching unit 100 and to an application executed by the control unit 110.

Alternatively or additionally, feedback could also be provided from the switching unit 100 to a higher-level control device connected to the switching unit 100. Furthermore, an error message could be issued at the switching unit 100 or by the higher-level control device not shown in FIG. 1, which could be as follows, for example: “Attention, internal error, switch-off via relay”.

For measuring the supply voltage, control unit 110 has a voltage measuring device 112 which measures the voltage at measuring point 112m, wherein digital measured values that can be processed by the microprocessor of control unit 120 can be provided through A/D conversion. However, it is likewise possible that the voltage measuring device 112 essentially provides only digital information as to whether the power supply of the unit is still active so as to still have a maximum of time for performing the switch-off sequence. Therefore, the voltage measuring device 112 could alternatively also be implemented as a digital input.

The measuring of the supply voltage in particular furthermore serves to detect, during the functional check described above, whether the supply voltage drops or is switched off during the predetermined period of time during which the energy storage 120 is disconnected from the supply voltage by opening the switch 140, in order to determine whether the undershooting of the second threshold value is due to a reduced operability of the energy storage 120 or to a drop or failure of the supply voltage.

In order to be able to measure the voltage at energy storage 120 independently of the applied supply voltage, a diode 134 is provided for decoupling purposes.

Generally, for monitoring the operability of the energy storage 120, the switching unit 100 preferably comprises at least one measuring device 114 connected to the control unit 110, for measuring a measurand or variable associated with the energy storage 120, which is a measure of the energy stored in the energy storage 120, and a means 140 for disconnecting the energy storage 120 from the supply voltage, which is controllable by the control unit 110, wherein the control unit 110 is adapted to disconnect the energy storage 120 from the supply voltage at predetermined times for a predetermined period of time, to measure the variable associated with the energy storage 120, and to compare the measured value with a predetermined threshold value, wherein the control unit 110 is further adapted to determine the operability of the energy storage 120 on the basis of the comparison result, and wherein the energy storage 120 is dimensioned so that in the operational state of the energy storage 120, the energy stored in the energy storage 120 does not fall below the energy required to execute the predetermined switching operation during the predetermined period of time.

As already mentioned above, the predetermined switching operation preferably comprises a switching sequence for safe disconnection of the electrical load 400 switched on and off via the at least one switching element 210, 221, 222, 310, 321, and 322.

It should be noted that when the three-phase motor 400 is switched on, the electromechanical switches 210 and 310, as well as 222 and 322 are closed and retained in this switching state by a holding current provided by the control unit 110, and the semiconductor switches 221 and 321 are switched off.

In the switching sequence, also referred to as switch-off sequence below, first the semiconductor switches 221 and 321 are switched on, and the electromechanical switches 222 and 322 are opened without load. Then, the semiconductor switches 221 and 321 are switched off, thus interrupting the power supply of the three-phase motor 400, and thereafter the electromechanical switches 210 and 310 are opened without load.

The switching on of the electrical load 400 is effected by a switching sequence with reverse order, i.e. the electromechanical switches 210 and 310 are closed, the semiconductor switches 221 and 321 are switched on, after switching on the semiconductor switches 221 and 321, the electromechanical switches 222 and 322 are closed and take over, as a bypass, the current flow from semiconductor switches 221 and 321, which are switched off after closing the electromechanical switches 222 and 322. As already mentioned above, the electromechanical switches 210, 222, 310, and 322 are preferably implemented as relays. In the switched-on state, the relay coils are continuously driven, wherein in this holding phase only a smaller magnetizing current is required in the relays than is required for throwing the relays.

In order to ensure better energy efficiency, in a preferred embodiment of the switching unit 100 the control unit 110 is adapted to control at least one switching element using a pulse-width modulated switching signal. Particularly advantageously, a pulse-width modulated switching signal is used to control relays, such as switches 210, 222, 310 and 322, but a pulse-width modulated switching signal may also advantageously be used to control semiconductor switches such as TRIACs 221 and 321.

A pulse-width modulated signal is an electrical signal that alternates between at least two voltage values and/or current values during a time period. Preferably, a pulse-width modulated signal is a square wave signal, although other signals are also within the scope of the invention. Unless stated otherwise, a square wave signal shall be assumed below. A pulse-width modulated signal comprises a periodic sequence of pulses, wherein the duty cycle of a pulse-width modulated signal indicates the ratio of pulse duration or pulse width to the period duration.

For example, since for controlling a relay, different magnetization currents are required depending on the respective switching situation, i.e. depending on whether currently the relay is to be thrown or the relay is continuously driven, the duty cycle of the pulse-width modulated switching signal is controlled by the control unit preferably depending on the switching state of the switching element, in particular depending on the respectively required electric power for the controlling.

In order to compensate for fluctuations in the supply voltage, the duty cycle of the pulse-width modulated switching signal may, alternatively or additionally, also be controlled, by the control unit, as a function of the supply voltage. Since the electrical energy required for controlling a switching element typically also depends on the ambient temperature, the duty cycle of the pulse-width modulated switching signal may, alternatively or additionally, also be controlled, by the control unit, as a function of an ambient temperature of the respective switching element. For example, the required triggering current for thyristors and TRIACs is strongly dependent on the temperature of the semiconductors, requiring a higher triggering current at low temperatures. However, at high temperatures, a higher triggering current leads to unnecessary losses. Advantageously, it is in particular possible for the duty cycle of the pulse-width modulated switching signal to be controlled individually for each switching element that is controlled by the control unit 110.

In order to determine the respective parameters, such as the switching state, or the electrical energy currently required for the controlling, or the ambient temperature, respective measuring devices are advantageously provided, not shown in FIG. 1.

In particular when the 24 V supply voltage is switched off and the voltage at energy storage 120 drops, as it happens for the above-described monitoring of the operability of energy storage 120, the duty cycle of the pulse-width modulated switching signals is advantageously adapted in order to be able to maintain the required magnetizing current in the relay as long as possible. In this way, the available stored energy can be maximally utilized, and energy storage 120 can be dimensioned as small as possible.

For example, if the supply voltage drops to 15 V, the duty cycle of the pulse-width modulated signals may be set to about 50%, and if the supply voltage rises to 30 V, the duty cycle of the pulse-width modulated switching signals may be lowered to about 25%. By adapting the pulse width modulation, it is possible to dimension the capacitor 120 to about one quarter of the usual value which would be determined on the basis of worst case assumptions, for example.

Another benefit lies in energy savings, which also allows for a smaller and thus more favorable dimensioning of the components in the internal power supply 150 of the unit. Due to the adapted duty cycle of the pulse-width modulated switching signals, only the energy that is actually necessary for the operation of the relay in the respective situation is consumed in each case.

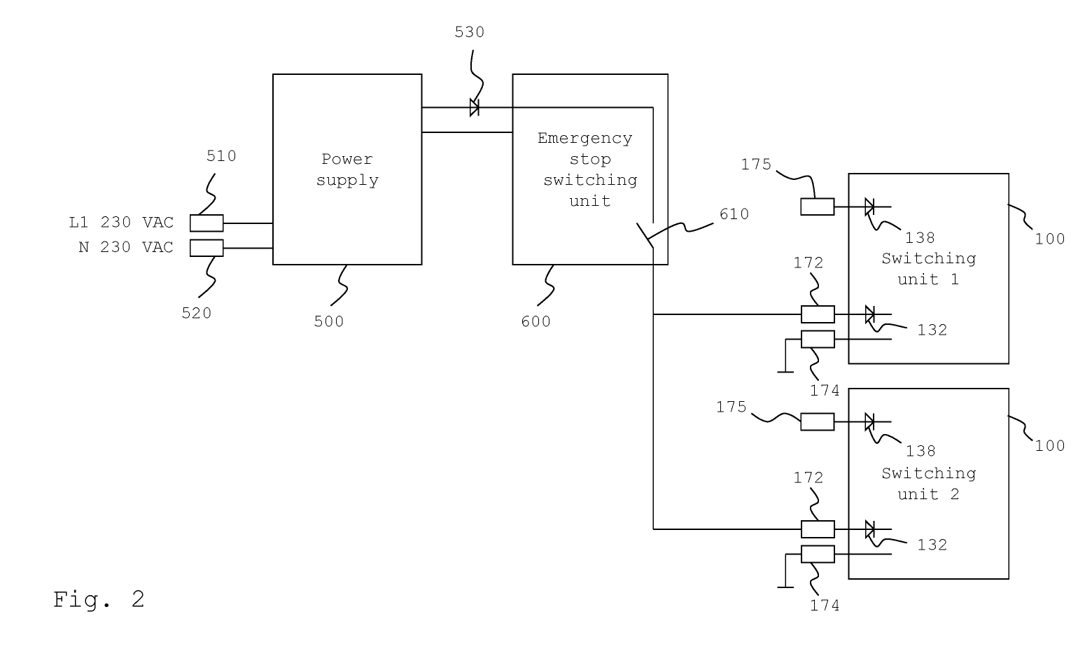

FIG. 2 schematically illustrates a plurality of switching units 100 connected to a shared emergency stop chain.

In the illustrated exemplary embodiment, two switching units 100 are connected to the power supply 500 which may be implemented as a 24 V power supply unit, for example, via an emergency stop switching unit 600. In particular, a current path is provided from the power supply to the connection terminals 172 of the switching units 100, which can be interrupted by opening the emergency stop switch 610 of emergency stop switching unit 600. Connection terminals 174 of switching units 100 are connected to ground. In the illustrated exemplary embodiment, the power supply unit 500 is connected, via terminals 510 and 520, to a single-phase low-voltage power grid, which may be provided by an L1 conductor and an N conductor of the three-phase low-voltage power grid illustrated in FIG. 1. The diode 530 shown in FIG. 2 serves for polarity reversal protection, for example.

It is often common practice to connect more than one unit to the power supply 500 or to the emergency stop chain, which may also include a plurality of units, also including different units. For the sake of simplicity, only two exemplary switching units 100 are shown in FIG. 2.

As has been described in conjunction with FIG. 1, switching units 100 include an energy storage 120 in the input circuit of the unit's power supply, which provides the necessary energy for a sequential switch-off in case of a failure of the unit's power supply. Therefore, it is particularly advantageously contemplated to prevent energy drainage to other units by a decoupling measure at the input of the unit. This is achieved by the diodes 132 in the example illustrated in FIG. 2.

Furthermore, terminals 175 of switching units 100 are illustrated in FIG. 2, which can be used to connect the switching units 100 to a higher-level switching device, not shown, from which they may receive switching commands, for example, for switching on or off the three-phase motor 400. Favorably, these terminals 175 also have a respective diode 138 connected thereto.

The decoupling through diodes 132 is also useful to bridge voltage fluctuations or interruptions in the 24 V power supply. Without the decoupling, faster discharge of the energy storage 120 might occur, and thus possibly an uncontrolled shutdown.

The decoupling allows to utilize the energy in energy storage 120 until the voltage at the energy storage has dropped to a critical point, in particular to the second threshold value described above, below which the switch-off of three-phase motor 400 is initiated.

Advantages of the decoupling include that in case of failure of the supply voltage, a sequential switch-off of the output stage is guaranteed, susceptibility to voltage fluctuations is reduced, longer availability is ensured when the supply voltage drops, short interruptions of the supply voltage can be bridged, and the energy provided in energy storage 120 is fully available to the respective switching unit 100.

The diode 132 for decoupling in order to avoid draining of electrical energy from the energy storage 120 to other units is also provided in the switching unit 100 shown in FIG. 1. However, this function may also be fulfilled by diode 134, so that in the case of the switching unit shown in FIG. 1, diode 132 could advantageously also be dispensed with.

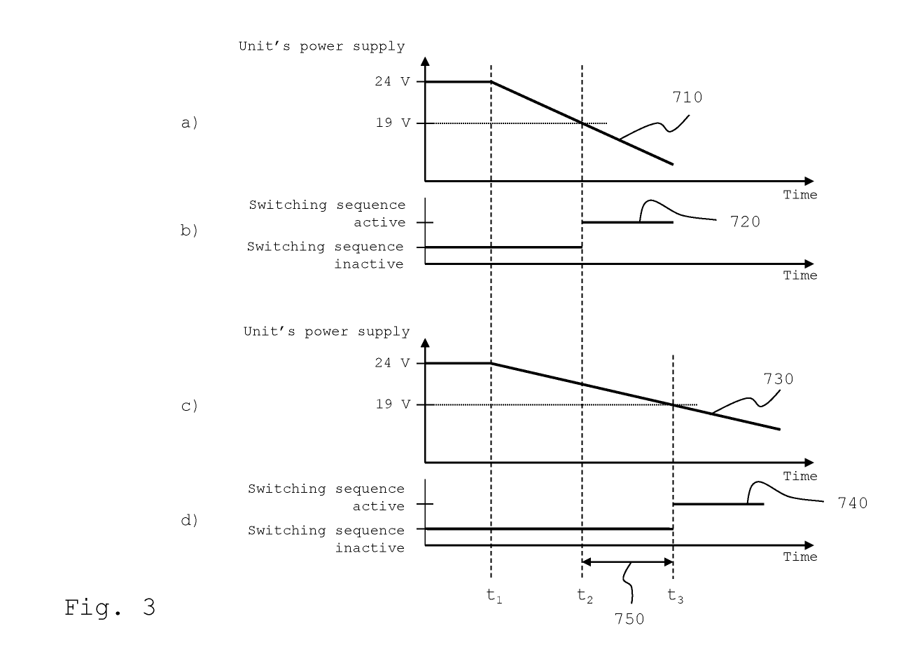

FIG. 3 schematically illustrates the effect of the use of a diode for decoupling purposes.

FIGS. 3 a) and b) exemplary illustrate the situation which would be given without the use of a diode for decoupling from other units. FIG. 3 a) shows an exemplary voltage profile 710 of the unit's power supply, i.e. the profile of the voltage at energy storage 120. In the illustrated example, the voltage drops sharply after time t₁, since for example the voltage of the power supply has dropped and energy is drained from energy storage 120 by other units. When the second threshold value is undershot, which is 19 V in the illustrated example, the switch-off sequence is activated, i.e. switch-off of the three-phase motor 400 is initiated. This is schematically shown in FIG. 3 b) by curve 720, which indicates whether the switching sequence is active or inactive.

FIGS. 3 c) and d) exemplary illustrate the situation which is given if a diode is used for decoupling from other units. FIG. 3 c) shows an exemplary voltage profile 730 of the unit's power supply, i.e. the profile of the voltage at energy storage 120. In the illustrated example the voltage decreases after time t₁, at which for example the voltage of the power supply has dropped, wherein the voltage decrease is not due to the fact that energy is drained from energy storage 120 by other units. Therefore, it will only happen at time t₃ that the threshold value of 19 V is undershot and the switch-off sequence is activated, i.e. the switch-off of the three-phase motor 400 is initiated. This is schematically illustrated in FIG. 3 d) by curve 740.

Thus, additional availability is resulting, as indicated by reference numeral 750, because the switch-off is delayed by the difference between t₃ and t₂.

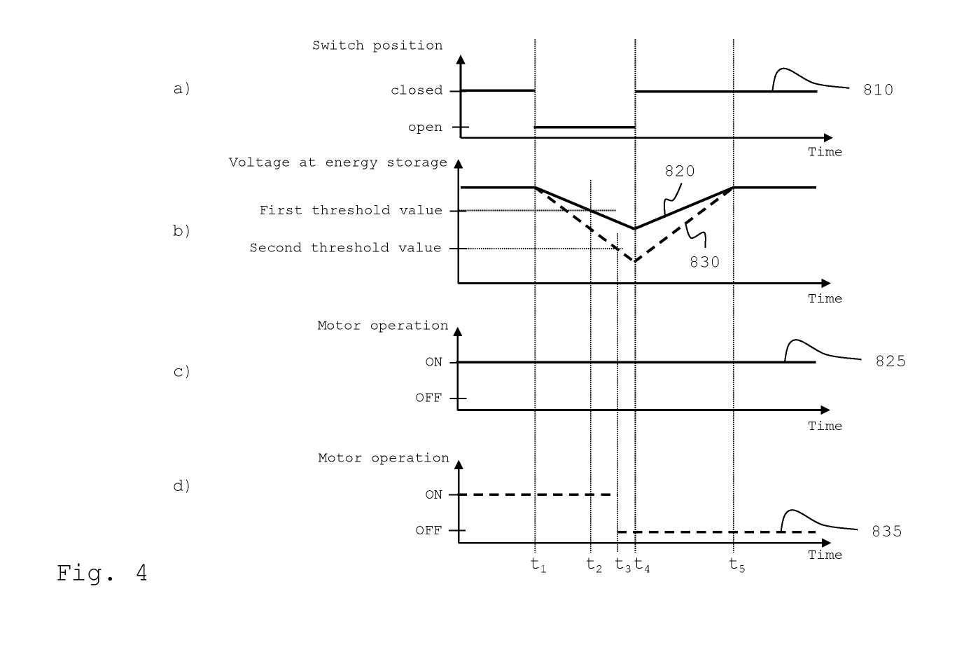

FIG. 4 again schematically illustrates the sequence of a functional check of the energy storage 120. The process illustrated in FIG. 4 is preferably repeated at predetermined times, in particular cyclically, in order to monitor the operability of energy storage 120.

FIG. 4 a) illustrates the time course 810 of the switch position of switch 140. During normal operation, switch 140 is initially closed. For checking the operability of energy storage 120, switch 140 is opened at time t₁, under control of control unit 110, and is closed again at time t₄. By opening switch 140, the energy storage 120 is disconnected from the power supply and the voltage at energy storage 120 decreases until time t₄. By closing the switch, the energy storage 120 is reconnected to the power supply and is accordingly recharged until again reaching its fully charged state at time t₅.

The voltage profile at energy storage 120 is illustrated in FIG. 4 b), the solid line 820 representing the voltage curve of a fully operative energy storage 120 and the dashed line 830 representing the voltage curve of a defective energy storage 120.

A first threshold value will be undershot even if the energy storage 120 is fully operative, namely at time t₂ in the illustrated example, wherein, as already mentioned above, this threshold value serves to detect whether the mechanism of the functional check, i.e. the disconnecting of the energy storage 120 from the power supply by triggering switch 140 works properly.

The second threshold will not be undershot if the energy storage 120 is fully operative. However, if the energy storage 120 is defective, this will happen, namely at time t₃ in the illustrated example.

By undershooting the second threshold value, a switch-off of motor 400 is initiated.

Lines 825 and 835 shown in FIGS. 4 c) and d), respectively, represent the motor operation, i.e. whether the motor 400 is on (ON) or off (OFF), in FIG. 4 c) for a fully operational energy storage 120, and in FIG. 4 d) for a defective energy storage 120.

It should be noted that the respective operating state of the motor as illustrated in FIGS. 4 c) and d) has to be regarded as a logical state in the control application of control unit 110, and that in the case of a defective energy storage 120 the switch-off sequence is initiated at time t₃, but the motor will be disconnected from the power supply and thus actually switched off only during the course of the switch-off sequence, when TRIACs 221 and 321 are switched off after opening switches 222 and 322, as described above.

It should also be noted that the functional check is repeated in time intervals that are short enough to ensure that even if energy storage 120 is detected to be defective, it still has sufficient operational power to ensure a safe switch-off. For example, in an advantageous embodiment a functional check can be performed once a day, i.e. at time intervals of 24 operating hours. However, it is also possible to choose other suitable time intervals which are higher or lower by at least or at most a factor of 2, 5, 10, 20, or 100, for example.

Monitoring, i.e. continuous checking of the operability of the energy storage 120 as proposed by the invention is particularly advantageous for continuously operating applications such as pumps or fans. Since aging usually manifests itself as a reduction in capacity, failure of the energy storage might occur with no sequential switch-off being performed, so that the relays might fuse. Especially continuous operation and high temperatures can lead to rapid aging of the energy storage capacitor, and switching units known from the prior art do not detect such aging, especially in devices used in continuous operation.

### LIST OF REFERENCE NUMERALS

100 Switching unit
110 Control unit
112, 114 Voltage measuring devices
112m, 114m Measuring points for voltage measurement
120 First energy storage
132, 134 Diodes
138 Diode
140 Controllable switch
150 Power supply 3.3 V
160 Second energy storage
172, 174 Terminals for applying a supply voltage
175 Terminal for controlling by a higher-level control device
180 Link for controlling the controllable switch
191-194 Controlling of electromechanical switches
195, 196 Controlling of TRIACs
210, 310 Electromechanical switches, in particular relays
220, 320 Hybrid switch
221, 321 TRIACs
222, 322 Electromechanical switches, in particular relays
400 Electrical load, in particular electric motor
401-403 Current paths
500 Power supply source, e.g. 24 V power supply unit
510, 520 Terminals for connection to a power grid
530 Diode
600 Emergency stop switching unit
610 Emergency stop switch
710 Voltage profile without diode
720 Activity profile of the switching sequence without diode
730 Voltage profile with diode
740 Activity profile of the switching sequence with diode
750 Duration of additional availability
810 Time sequence of switch position
820 Voltage profile at energy storage in case of operational energy storage
825 Motor operation in case of operational energy storage
830 Voltage profile at energy storage in case of defective energy storage
835 Motor operation in case of defective energy storage

1. A switching unit for controlling at least one switching element, comprising:
a control unit adapted to control the at least one switching element;
a connection for applying a supply voltage for power supply of the control unit;
an energy storage connectable to the connection for applying a supply voltage and adapted, when the supply voltage drops or fails, to supply the control unit with power sufficient to control the at least one switching element such that the switching element executes a predetermined switching operation;
wherein the switching unit comprises means for monitoring the operability of the energy storage.

2. The switching unit as claimed in claim 1, further comprising at least one measuring device connected to the control unit for measuring a parameter associated with the energy storage which parameter is a measure of the energy stored in the energy storage and a means for disconnecting the energy storage from the supply voltage, which is controllable by the control unit wherein
the control unit is adapted to disconnect the energy storage from the supply voltage at predetermined times for a predetermined period of time, to measure the parameter associated with the energy storage and to compare the measured value with a predetermined threshold value; wherein
the control unit is further adapted to determine the operability of the energy storage on the basis of the comparison result; and wherein the energy storage is dimensioned so that in the operational state of the energy storage the energy stored in the energy storage does not fall below the energy required to perform the predetermined switching operation during the predetermined period of time.

3. The switching unit as claimed in claim 2, wherein the energy storage is implemented as a capacitor, the parameter associated with the energy storage is the voltage provided by the capacitor, and the measuring device for measuring the parameter associated with the energy storage is implemented as a voltage measuring device.

4. The switching unit as claimed in claim 1, adapted, upon detection that the operability of the energy storage is reduced by a predetermined amount, to control the at least one switching element such that the switching element executes the predetermined switching operation, and/or to generate an error message.

5. The switching unit as claimed in claim 1, wherein the predetermined switching operation comprises a switching sequence for safe switch-off of an electrical load that is switched on and off via the at least one switching element.

6. The switching unit as claimed in claim 1, comprising a decoupling device for decoupling the switching unit from further units, in particular further switching units which are connected to the supply voltage, wherein the decoupling device is adapted to prevent energy stored in the energy storage from draining to the further units, and wherein the decoupling device in particular comprises at least one diode.

7. The switching unit as claimed in claim 1, wherein the control unit is adapted to control the at least one switching element using a pulse-width modulated switching signal, wherein the duty cycle of the pulse-width modulated switching signal is controlled by the control unit as a function of the switching state of the switching element, and/or as a function of the supply voltage, and/or as a function of an ambient temperature of the switching element.

8. The switching unit as claimed in claim 1, comprising a voltage measuring device connected to the control unit for monitoring the supply voltage.

9. A method for controlling at least one switching element using a switching unit according to claim 1, comprising the steps of:
applying a supply voltage to the switching unit for power supply of a control unit of the switching unit, the at least one switching element being controlled by said control unit;
if the supply voltage drops or fails, supplying the control unit with power sufficient to control the at least one switching element such that the switching element executes a predetermined switching operation, using an energy storage that is connectable to the supply voltage; and
monitoring the operability of the energy storage.

10. The method as claimed in claim 9, comprising, at predetermined times, in particular cyclically,
disconnecting the energy storage from the power supply device for a predetermined period of time, wherein the predetermined period of time is selected such that in the operational state of the energy storage the energy stored in the energy storage does not fall below the energy required to execute the predetermined switching operation during said predetermined period of time;
measuring a parameter associated with the energy storage, which is a measure of the energy stored in the energy storage;
comparing the measured value with a predetermined threshold value; and
determining the operability of the energy storage on the basis of the comparison result.

11. The method as claimed in claim 9, wherein upon detection that the operability of the energy storage is reduced by a predetermined amount, the at least one switching element is controlled such that the switching element executes the predetermined switching operation, and/or an error message is generated.

12. The method as claimed in claim 9, wherein the predetermined switching operation comprises a switching sequence for safe switch-off of an electrical load switched on and off via the at least one switching element.

13. The method as claimed in claim 9, comprising decoupling the switching unit from further units, in particular further switching units connected to the supply voltage, so as to prevent energy stored in the energy storage from draining to the further units.

14. The method as claimed in claim 9, wherein the control unit controls the at least one switching element using a pulse-width modulated switching signal, wherein the duty cycle of the pulse-width modulated switching signal is controlled by the control unit as a function of the switching state of the switching element, and/or as a function of the supply voltage, and/or as a function of an ambient temperature of the switching element.

15. The method as claimed in claim 9, wherein the supply voltage is monitored using a voltage measuring device connected to the control unit.
